(19) United States
(12) Patent Application Publication
(10) Pub. No.: US 2006/0014374 A1
(43) Pub. Date: Jan. 19, 2006

(54) Layer assembly and method for producing a layer assembly

(76) Inventors: Hans-Joachim Barth, Lutzowstr. 19A (DE); Recai Sezi, Weiherstr. 14 (DE)

Correspondence Address: BRINKS HOFER GILSON & LIONE;INFINEON, PO BOX 10395, CHICAGO, IL, 60610, US

(21) Appl. No.: 10/518,880

(22) PCT Filed: Jun. 3, 2003
(86) PCT No.: PCT/DE03/01827

§ 371 Date: Aug. 8, 2005

(30) Foreign Application Priority Data
Jun. 20, 2002 (DE) 102 27 615.3

(51) Int. Cl. H01L 21/4763

(52) U.S. Cl. 438/622

(57) ABSTRACT

The invention relates to a layer arrangement and to a process for producing a layer arrangement. The layer arrangement has a layer which is arranged on a substrate and includes a first subregion comprising decomposable material and a second subregion which is arranged next to the first subregion and has a useful structure comprising a non-decomposable material. Furthermore, the layer arrangement has a covering layer on the layer comprising decomposable material and the useful structure, the layer arrangement being designed in such a manner that the decomposable material can be removed from the layer arrangement.

The invention relates to a layer arrangement and to a process for producing a layer arrangement.

Electrically insulating layers are required for numerous applications in semiconductor technology, in particular during the formation of integrated circuits. If insulation layers are formed in an integrated circuit in which electrically conductive regions, in particular interconnects, are also present, a coupling capacitance may result between adjacent interconnects and a dielectric layer arranged between them. The capacitance of two parallel interconnects whose surfaces which adjoin one another, which are denoted by A and are arranged at a distance d from one another, with a relative permittivity ε of the dielectric corresponds to:
C=εA/d (1)

With ongoing miniaturization of silicon microelectronics, i.e. with a decrease in distance d between adjacent interconnects, a high coupling capacitance C results in particular if the surfaces A of the interconnects which adjoin one another are large, i.e. if the interconnects run parallel to one another over a considerable length in the integrated circuit.

With ongoing miniaturization of an integrated circuit, problems with coupling capacitances are increasing. The propagation time of a signal in an interconnect increases as the coupling capacitance rises, since this propagation time is determined by the product of Ohm resistance R and capacitance C (known as the “RC delay”).

As can be seen from Equation (1), for fixed structure dimensions A, d it is possible to reduce a coupling capacitance C if the relative permittivity ε of the insulating material is reduced. Therefore, it is attempted to use materials with a low relative permittivity ε (what are known as “low k materials”) as materials for insulation layers in integrated circuits.

Amorphous silicon dioxide (SiO₂) with a relative permittivity of approximately 4.0 is often used as dielectric for electrically decoupling metallic interconnects with respect to one another.

The performance of advanced semiconductor chips (0.18 μm technology and below) is being adversely affected to an increasingly serious degree by the RC delay of the interconnects. Therefore, silicon dioxide is no longer suitable as dielectric material for future high-performance requirements.

From the 0.13 μm technology generation and below, low-k dielectrics with dielectric constants of typically less than 3 are increasingly being used. Examples of these dielectrics include SiLK™ with k≈2.7, OxD (oxazole dielectric) with k≈2.5, Black Diamond™ with k≈2.9, Coral™ with k≈2.9.

It is possible to further reduce the relative permittivity of electrically insulating layers by introducing cavities into “low-k material”, since a (vacuum) cavity under ideal conditions has a k value of k=1. The k value of the porous material is reduced as a function of the volumetric proportion made up of cavities or pores. For future technology generations, increasingly porous materials will be used, such as for example porous SiLK with k≈2.2, porous OxD with k≈2.1, Nanoglass with k≈2.2 or JSR-LKD (low-k dielectric produced by the company JSR) with k≈2.2.

Even porous low-k materials are still far removed from the theoretical optimum k=1 (vacuum or approximately air).

It is known from [1], [2] to use what are known as air gaps, i.e. intermediate regions which are free of solid-state material, between interconnects as intermetal dielectric. However, this known structure has the drawback in particular of being based on the non-conformal deposition of silicon dioxide or a CVD (chemical vapour deposition) low-k material (SiOC). Although it is in this way possible to form air gaps, the silicon dioxide or SiOC is partially retained, and consequently the effective dielectric constant which can be achieved is only insignificantly below the value k=2.

[3] discloses a copper/air hole structure which is produced using a sacrificial polymer and a silicon oxide layer.

[4] discloses a process for producing a semiconductor component in which a layer provided with holes is formed above interconnects formed on a substrate, material located between the interconnects being discharged through the holes.

[5] discloses a layer arrangement having interconnects on a substrate and a porous layer on the interconnects, with material of sacrificial structure between the interconnects being vapourized and discharged through the porous layer.

[6] discloses an integrated circuit with air holes between dielectric and electrically conductive lines.

The invention is based on the problem of providing a layer arrangement in which a parasitic capacitance of components of a useful structure is reduced compared to the prior art.

The problem is solved by a layer arrangement and by a process for producing a layer arrangement having the features described in the independent patent claims.

The layer arrangement according to the invention includes a layer which is arranged on a substrate and includes a first subregion comprising decomposable material and a second subregion which is arranged next to the first subregion and has a useful structure comprising a non-decomposable material. Furthermore, the layer arrangement has a covering layer on the layer comprising decomposable material and the useful structure. The layer arrangement is designed in such a manner that the decomposable material can be removed from the layer arrangement.

Furthermore, the invention provides a process for producing a layer arrangement, in which a layer which includes a first subregion comprising decomposable material and a second subregion which is arranged next to the first subregion and comprises a useful structure comprising a non-decomposable material is formed on a substrate. Furthermore, a covering layer is formed on the layer comprising decomposable material and the useful structure. The layer arrangement is designed in such a manner that the decomposable material can be removed from the layer arrangement.

Clearly, the invention creates a layer arrangement having a layer which is embedded between two layers and includes decomposable material and a useful structure. The useful structure may, for example, include interconnects of an integrated circuit. Parasitic capacitances may occur between interconnects of the useful structure, and in accordance with equation (1) the magnitude of these capacitances increases with the level of the relative permittivity of the decomposable material arranged between the interconnects. According to the invention, the decomposable material in combination with the covering layer is designed in such a manner that by suitable treatment of the layer arrangement (for example by means of temporary annealing), the decomposable material can be thermally decomposed or vapourized. In this way, the decomposable material is removed from the layer arrangement by preferably diffusing through the covering layer. After a treatment of this nature, regions between components of the useful structure are free of decomposable material, which has now decomposed, so that under ideal conditions a relative permittivity of ε=1 is obtained. In this way the RC delay is significantly reduced, since the capacitance C in accordance with equation (1) has been reduced. In this way, it is possible for adjacent interconnects to be arranged closer together while the signal propagation time remains constant, which is in line with the trend toward miniaturization in semiconductor technology. The parasitic capacitive coupling between interconnects, in particular in metallization levels of an integrated circuit, is therefore reduced in accordance with the invention. Consequently, the invention avoids the need for complex formation of pores or for complex patterning of a dielectric layer to produce cavities.

Clearly, dielectric material arranged between the interconnects of a metallization level can be removed. The interconnects are mechanically stabilized on both sides in the vertical direction by a layer (covering layer or substrate). Ideally, at least the covering layer is made from a material which is permeable to the decomposition products of the layer arranged in between and which is preferably itself a low-k material.

Preferred refinements of the invention will emerge from the dependent claims.

The layer arrangement may preferably include an intermediate layer between the substrate and the layer comprising decomposable material and the useful structure. The intermediate layer may be made from low-k material and/or may be designed in such a manner that the material of the useful structure is protected from diffusion out of the layer arrangement on account of the functionality of the intermediate layer.

The substrate may preferably include silicon and may in particular be a silicon wafer or a silicon chip. As a result, the processing of the layer arrangement can be incorporated in the standard processes used in silicon microelectronics.

The covering layer and/or the intermediate layer may be made from dielectric material. In particular, the covering layer and/or the intermediate layer may include silicon oxide, silicon nitride, SiLK, porous SiLK, oxazole, porous oxazole, Black Diamond, Coral, Nanoglass, JSR LKD, polybenzoxazoles, polybenzimidazoles, polyimides, polyquinolines, polyquinoxalines, polyarylenes and/or polyarylenethers.

The covering layer of the layer arrangement is preferably designed in such a manner that it is permeable to decomposable material which has decomposed. Furthermore, the covering layer is preferably designed in such a manner that it is protected from being destroyed or damaged when a decomposition process is being carried out. In particular, the covering layer should be protected from thermal decomposition or thermal damage during heating to a temperature range from approx. 250° C. to approx. 400° C. This temperature range is typical of a thermal decomposition process used to decompose the decomposable material. However, the precise decomposition temperature is dependent on the material selected in the individual case.

The useful structure may be made from an electrically conductive material, in particular from aluminium and/or copper and/or a dielectric material, such as silicon dioxide (SiO₂), silicon nitride (Si₃N₄) or ceramic material. Copper is a particularly suitable material for interconnects of an integrated circuit, since it has a very low ohmic resistance, with the result that the RC delay can be kept at a low level. Aluminium can both be deposited in planar form and then patterned or can be processed using a Damascene process. If copper is used as material for the useful structure, it is advantageous to form a copper structure by first of all depositing and patterning a dielectric layer and then introducing copper material into regions which are free of dielectric material by using the Damascene process. A layer sequence of this type can preferably be planarized using a CMP (chemical mechanical polishing) process. It should be emphasized that in the case of a useful structure made from an electrically insulating or dielectric material, an electrically conductive passivation is unnecessary at least between the useful structure and the covering layer.

The decomposable material is preferably thermally decomposable, i.e. can be removed from the layer arrangement by heating to a predetermined temperature for a predetermined time in a predetermined chemical medium (for example under protective gas atmosphere comprising argon, nitrogen or in vacuum). The decomposition temperature required is dependent primarily on the choice of material for the thermally decomposable layer. Furthermore, the decomposition temperature can be modified by using a mixture of different material components for the thermally decomposable structure. It is also possible to influence the decomposition temperature required by adjusting the other process parameters used in thermal decomposition (e.g. surrounding pressure, etc.).

Alternatively, the decomposable material may be decomposable in a manner other than thermally. For example, if the decomposable material has the property of sufficiently absorbing electromagnetic radiation in a suitable wavelength range (e.g. UV radiation), and if the absorption of electromagnetic radiation of this type by the covering layer is sufficiently low, the decomposable layer can be decomposed by radiating electromagnetic radiation onto the layer arrangement according to the invention.

Examples of suitable materials or classes of materials for the decomposable material are polyester, (predominantly aliphatic) polyether such as polyethyleneglycol, polypropyleneglycol, polyethyleneoxide or polypropyleneoxide. Polyacrylates, polymethacrylates, polyacetals, polyketals, polycarbonates, polyurethanes, polyetherketones, cycloaliphatic polymers, such as polynorbornene, predominantly aliphatic polyamides, Novolaks, polyvinylphenols and epoxy compounds are also suitable. Copolymers and terpolymers of the classes of materials cited here are also suitable.

The decomposable material is preferably photosensitive or photopatternable, such as for a example a resist.

In particular, a photopatternable resist may be one of the following combinations of a base polymer and a photoactive component or photoacid.

The polymer used may be: polyacrylates, polymethacrylates, polyacetals, polyketals, copolymers with maleic anhydride (such as styrene/maleic anhydride), aliphatic, aromatic or cycloaliphatic polymers with tert-butyl ester [(COOC(CH₃)₃] such as tert-butyl methacrylate or with tert-butoxycarbonyloxy groups [(OCOO(CH₃)₃], such as tert-butoxycarbonyloxystyrene (=t-BOC vinylphenol).

Examples of suitable photoactive components are diazoketones, diazoquinones, triphenylsulphonium salts or diphenyliodonium salts.

Examples of suitable solvents for dielectric materials, resist or the decomposable material which is temporarily used are methoxypropyl acetate, ethoxypropyl acetate, ethoxyethyl propionate, N-methylpyrrolidone, gamma-butyrolactone, cyclohexanone or cyclopentanone.

In the case of the layer arrangement according to the invention, at least one supporting structure is preferably formed in the layer arranged between the substrate and the covering layer. To improve the mechanical properties, it may be advantageous to use a supporting structure of this type, preferably made from metallic material, where the chip layout means that there are sufficiently large material-free regions. The supporting structure may, for example, be formed as a support pillar. Support pillars for mechanical stabilization are advantageous in particular beneath the bond pads.

Furthermore, the layer arrangement may have a protective structure which runs substantially along the lateral boundary of the substrate in order to protect the useful structure from environmental influences. Clearly, a protective ring (sealing ring) which is impermeable all the way around and comprises preferably at least two 2 μm wide metal tracks and preferably multiple likewise uninterrupted longitudinal vias may be formed at the edge of the chip in order to avoid corrosion or oxidation of the useful structure produced as interconnects in the interior of the chip commencing from the edge of the chip.

The useful structure may be at least partially surrounded by a passivation layer (liner). Particularly when copper is used as material for the useful structure, a diffusion barrier for preventing outdiffusion of the copper material or for improving the bonding of the copper material is advantageous.

The text which follows provides a more detailed description of the process according to the invention for producing the layer arrangement. Configurations of the layer arrangement also apply to the process used to produce the layer arrangement.

It is preferable for the decomposable material to be removed from the layer arrangement, for example by means of thermal decomposition.

According to the process for producing a layer arrangement, the useful structure may be formed from copper and may be at least partially surrounded by a passivation layer, which passivation layer is formed from cobalt-tungsten-phosphorus (CoWP), cobalt-tungsten-boron (CoWB), cobalt-phosphorus (CoP) or ruthenium (Ru) by means of a (preferably selective) electroless deposition process. Alternatively, the passivation layer may be formed from tantalum (Ta), tantalum nitride (TaN), titanium nitride (TiN), tungsten (W), tungsten nitride (WN) or tungsten carbide (WC) by means of a (preferably selective) chemical vapour deposition process (CVD process).

The layer comprising decomposable material and the useful structure may be formed by decomposable material being deposited and patterned (e.g. using a lithography process and an etching process), material of the useful structure being deposited and the surface of the layer sequence obtained in this way being planarized (for example using a CMP, “chemical mechanical polishing” process). This process is particularly advantageous when copper is used as material for the useful structure.

Alternatively, the layer comprising decomposable material and the useful structure can be formed by depositing and patterning (e.g. using a lithography process and an etching process) material of the useful structure and depositing decomposable material. If a metallic material is used for the useful structure, for example aluminium or copper, this process for forming the useful structure is referred to as a Damascene process. The surface of the layer sequence obtained in this way can then be planarized (e.g. using a CMP process).

According to the process of the invention, it is possible for at least one additional layer stack to be formed on the covering layer, the additional layer stack having an additional covering layer on an additional layer comprising decomposable material and a useful structure.

Obviously, two or more levels of the layer arrangement according to the invention can be formed on top of one another. In this case, the layer arrangement includes a substrate, a first layer comprising useful structure and thermally decomposable material arranged thereon, a first covering layer formed thereon, a second layer comprising useful structure and decomposable material formed thereon, a second covering layer formed thereon, a third layer comprising useful structure and decomposable material formed thereon, a third covering layer, and so on.

In other words, a multiplicity of layer arrangements according to the invention can be stacked on top of one another, which is advantageous in particular when a plurality of metallization levels are being formed in silicon microelectronics (typically up to ten metallization levels). To remove the decomposable material from the layer arrangement with the minimum possible number of working steps, it is possible to use a joint decomposition process (e.g. a thermal process) after all or some of the layers have been formed. To ensure particularly reliable and complete removal of the decomposable material on the layer arrangement, it is alternatively possible to subject a double layer comprising a layer comprising useful structure and decomposable material and a covering layer to a decomposition process after each double layer of this type has been formed. In other words, each double layer is exposed to a separate decomposition process.

It is preferable for useful structures which are separated from one another by a covering layer to be electrically and/or mechanically coupled to one another by at least one contact hole being formed in the covering layer and filled with electrically conductive material.

The text which follows lists a number of typical values and materials. The thickness of the intermediate layer is preferably between 100 nm and 1000 nm. Preferred layer thicknesses for the layer comprising decomposable material and the useful structure are between approximately 100 nm and approximately 1000 nm. A typical thickness for a photoresist for patterning a layer below is preferably between 200 nm and 1000 nm. In addition, it is possible to provide an anti-reflection layer (for example a BARC, Bottom Anti-Reflective Coating).

For lithography processes during the formation of the layer arrangement according to the invention, it is possible, for example, to use the wavelengths 248 nm, 193 nm, 157 nm or a wavelength in the extreme ultraviolet (EUV lithography).

To summarize, it can be concluded that a thermally decomposable or vapourizable material which can diffuse through the covering layer without problems as it decomposes creates a new way of forming cavity structures, in particular as low-k dielectrics, which are mechanically closed off with respect to the outside. Air gaps can be produced in particular between interconnects of an integrated circuit by the decomposable material being decomposed. In this way, it is possible to significantly reduce the capacitive coupling of the interconnects and therefore the RC signal delay.

Furthermore, the invention provides a simple process for producing the layer arrangement according to the invention which can be realized using standard processes. The invention can also be used as part of a multilayer metallization, for example for a plurality of metallization levels of an integrated circuit. Mechanical support structures and a support ring, preferably at the edge of the chip, increase the mechanical stability of the layer arrangement.

Exemplary embodiments of the invention are illustrated in the figures and are explained in more detail below.

In the drawing:

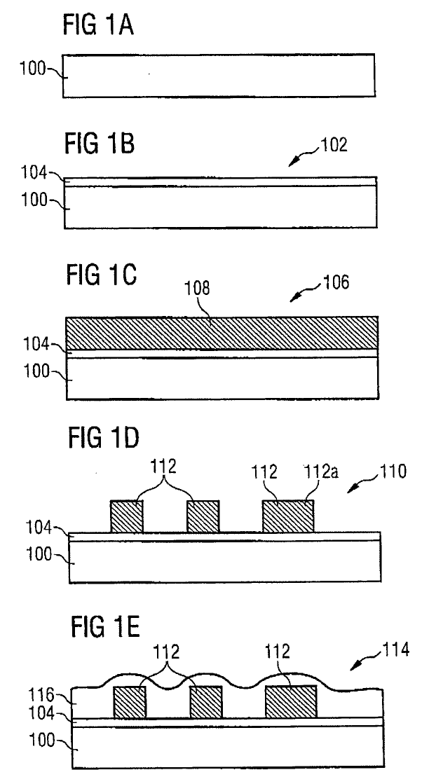

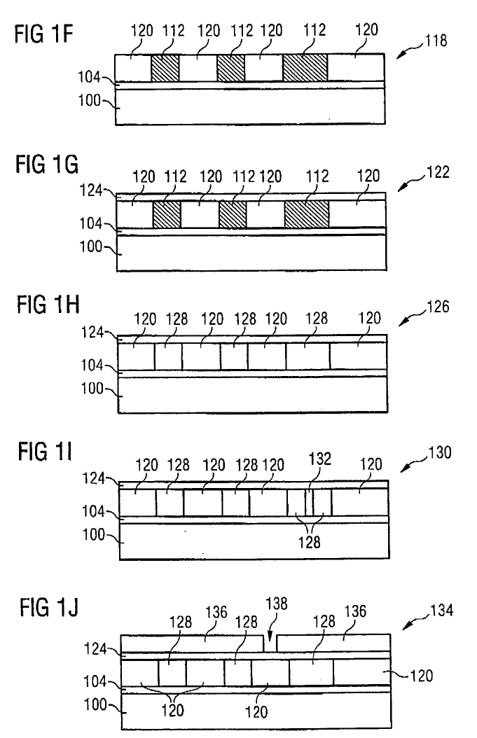

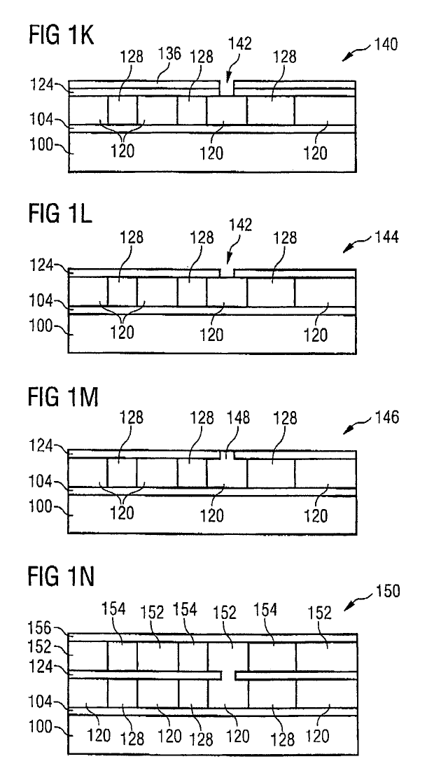

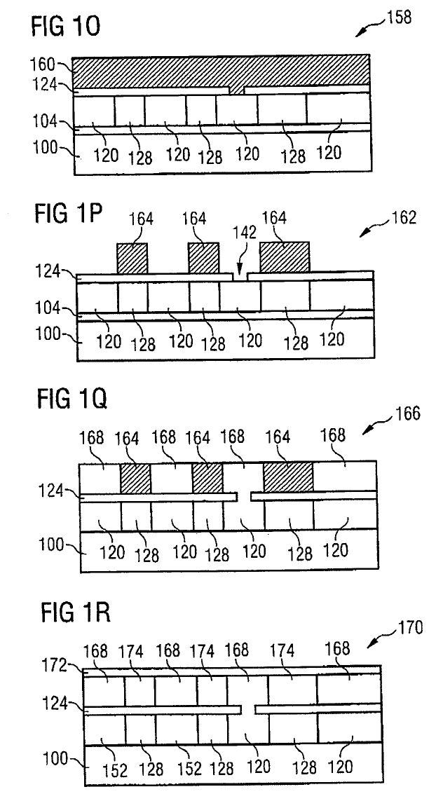

FIGS. 1A to 1R show layer sequences at different times during processes according to the invention for producing a layer arrangement according to the invention in accordance with different exemplary embodiments of the invention.

The following text, referring to FIG. 1A to FIG. 1H, describes a process for producing a layer arrangement in accordance with a first exemplary embodiment of the invention.

To obtain the layer sequence 102 shown in FIG. 1B, a bottom layer 104 comprising polybenzoxazole is formed on a silicon wafer 100 (cf. FIG. 1A). For this purpose, first of all a polybenzoxazole precursor (poly-o-hydroxyamide) is applied to the silicon wafer 100 from a solution in N-methylpyrrolidone by means of a spin-coating technique and is dried on a heating plate for approximately two minutes at approximately 120° C. Then, the coated silicon substrate 100 is annealed in an annealing furnace under a nitrogen atmosphere for approximately 60 minutes at approximately 420° C. The conditioning causes the polybenzoxazole precursor to be converted into polybenzoxazole material. The thickness of the dielectric bottom layer 104 is 1 μm.

To obtain the layer sequence 106 shown in FIG. 1C, an auxiliary layer 108 comprising photoresist is applied to the layer sequence 102. For this purpose, a decomposable and photoactive film comprising a copolymer of tert-butyl methacrylate and methylmethacrylate (20 parts by weight), a photo acid comprising triphenylsulphonium trifluoromethane-sulphonate and methoxypropyl acetate as solvent (80 parts by weight) is applied to the bottom layer 104 using a spin coating technique and is dried for approximately 1 minute at approximately 100° C.

To obtain the layer sequence 110 shown in FIG. 1D, the resist auxiliary layer 108 is exposed (exposure wavelength 248 nm) using a photomask (land-trench mask for the interconnects) is heated to 100° C. on a heating plate for 100 seconds (known as the post exposure bake), is developed with an aqueous-alkaline developer NMD-W produced by Tokya Ohka for approximately 60 seconds and is then dried at 100° C. for 1 minute. This results in a decomposable structure 112 comprising decomposable material being formed on the auxiliary layer 108. The vertical height, in accordance with FIG. 1D, of the decomposable structure 112 is approximately 1 μm.

To obtain the layer sequence 114 shown in FIG. 1E, the layer sequence 110 is coated with a thin layer combination of liner (tantalum material, 30 nm) and a copper seed layer (approximately 100 nm) using the PECVD (plasma enhanced chemical vapour deposition) process. Alternatively, a PVD (physical vapour deposition) process, i.e. a sputtering process, can also be used to apply these layers. The copper seed layer is then thickened by electro deposition in such a manner that all the trench regions between respectively adjacent components of the decomposable structure 112 are filled copper material. As shown in FIG. 1E, the vertical height of the copper material 116 in accordance with FIG. 1E is greater than the vertical height of the decomposable structure 112.

To obtain the layer sequence 118 shown in FIG. 1F, the copper material 116 is polished down using the CMP (chemical mechanical polishing) process until it forms a common planar surface with the decomposable structure 112. In other words, the copper material above the decomposable structure 112 has been ground away. To passivate the copper surface, a cobalt-tungsten-phosphorus layer, which is deposited selectively using an electroless deposition process, is applied (not shown in the figure). The copper material which remains forms the copper interconnects 120.

To obtain the layer sequence 122 shown in FIG. 1G, a further polybenzoxazole precursor is applied to the layer sequence 120 (in the same way as described above) and dried. As a result, a dielectric covering layer 124 comprising polybenzoxazole is formed.

To obtain the layer arrangement 126 in accordance with a first preferred exemplary embodiment of the invention shown in FIG. 1H, the layer sequence 122 is subjected to an annealing process. During the annealing of the polybenzoxazole dielectric at 420° C., the decomposable structure 112 comprising resist material below it is decomposed, so that cavities 128 remain. In this process step, the dielectric covering layer 124 is protected from being damaged, since the decomposed material of the decomposable structure 112 diffuses through the covering layer 124. Since the cavities 128 have a relative permittivity of approximately 1, the copper interconnects 120 form a reduced coupling capacitance with one another.

The text which follows describes a second preferred exemplary embodiment of the layer arrangement according to the invention.

For this embodiment, starting from the layer arrangement 126 shown in FIG. 1H, a further layer comprising decomposable material and regions with decomposable material arranged adjacent are formed on the covering layer 124 in the same way as in the process steps described with reference to FIG. 1A to FIG. 1H (not shown in the figure). A further dielectric covering layer is formed above the layer which has just been described, resulting in two interconnect levels one above the other. Each interconnect level is surrounded by a dielectric layer on both sides in the vertical direction. The process is not restricted to two levels, but rather it is possible for any desired number of levels to be formed and processed on top of one another.

The text which follows, referring to FIG. 1I, describes a layer arrangement 130 in accordance with a third exemplary embodiment of the invention.

The production process used to form the layer arrangement 130 is carried out substantially in the same way as described above with reference to FIG. 1A to FIG. 1H. The main difference between the process for producing the layer arrangement 130 and the process for producing the layer arrangement 126 consists in the fact that in the process step for patterning the auxiliary layer 108 to form the decomposable structure 112 which was described with reference to FIG. 1D, the patterning is carried out in such a manner that the component 112a of the decomposable structure 112 shown in FIG. 1D is additionally patterned in such a manner that component 112a is divided into two sub-components which are spatially decoupled from one another and between which there is a further cavity. The further cavity is filled with copper material in a process step which is analogous to the process step described with reference to FIG. 1E, so that during processing which is similar to that described with reference to FIG. 1F to FIG. 1H the layer arrangement 130 shown in FIG. 1I is obtained. This arrangement additionally has a copper support pillar 132 which is provided in order to improve the mechanical stability of the layer arrangement 130.

The text which follows, referring to FIG. 1A to FIG. 1H, FIG. 1J to FIG. 1N describes a process for producing a layer arrangement in accordance with a fourth exemplary embodiment of the invention.

In accordance with the fourth exemplary embodiment of the production process according to the invention, first of all the process steps which have been shown above with reference to FIG. 1A to FIG. 1H are carried out.

To obtain the layer sequence 134 shown in FIG. 1J, a photoresist layer 136 is applied to the layer sequence shown in FIG. 1H and patterned. The photoresist layer 136 is applied in a similar manner to the deposition of the auxiliary layer 108 described above with reference to FIG. 1C. Furthermore, the photoresist layer 136 is exposed using a contact hole mask. After a post exposure bake and the developing, a contact hole 138 is formed, located directly above one of the copper interconnects 120. As is also shown in FIG. 1J, the remaining surface of the covering layer 124 is covered with the photoresist layer 136.

To obtain the layer sequence 140 shown in FIG. 1K, the dielectric material of the covering layer 124 in the contact hole 138 is etched by means of an oxygen plasma for 100 seconds, with the result that the surface of one of the copper interconnects 120 is uncovered. This results in the formation of a via hole 142. To remove a layer of oxide which may be present on the surface of this copper interconnect 120, etching by means of an argon plasma is carried out for a further 20 seconds.

To obtain the layer sequence 144 shown in FIG. 1L, the remaining photoresist layer 136 is removed (stripped) by means of a two-minute treatment with N-methylpyrrolidone and the layer sequence thus obtained is dried at 120° C. for 60 seconds.

To obtain the layer sequence 146 shown in FIG. 1M, the via hole 142 is filled with copper material by electro deposition in order to form the copper contact 148.

To obtain the layer arrangement 150 shown in FIG. 1N, a further double layer, comprising a layer with decomposable material and additional copper interconnects 152 arranged next to one another and a further covering layer 156 is formed, as described above with reference to the second exemplary embodiment. Furthermore, the decomposable material is expelled by thermal means from the additional double layer which has been processed in this manner. As shown in FIG. 1N, this leads to the formation of additional cavities 154.

The text which follows describes a process for producing a layer arrangement in accordance with a fifth exemplary embodiment of the invention.

This exemplary embodiment represents a modification to the process for producing the layer arrangement 126 which has been described with reference to FIG. 1A to FIG. 1H. Unlike in the latter process, however, a low-k material, specifically the material SiLK™ (trademark of Dow Chemical Company) is used instead of a polybenzoxazole precursor as material for the bottom layer 104. Instead of the material for the auxiliary layer 108 which is used in accordance with the first exemplary embodiment, a resist having the following components is used: 20 parts by weight of polyvinlphenol, the phenolic hydroxyl groups of which are blocked with a tert-butoxycarbonyloxy grouping (poly-t-BOC-vinylphenol); 1 part by weight of diphenyliodonium trifluoromethanesulphonate as photo acid; and 80 parts by weight of epoxyethylacetate as solvent. Apart from the alternative materials used, a layer arrangement which substantially corresponds to the layer arrangement 126 shown in FIG. 1H is obtained.

In accordance with a process for producing a layer arrangement in accordance with a sixth exemplary embodiment of the invention, a layer arrangement similar to the layer arrangement 150 is formed as described above with reference to the fourth exemplary embodiment. However, according to the sixth exemplary embodiment, the components of the fifth exemplary embodiment are used as material for the photoresist and the dielectric.

The text which follows, referring to FIG. 1A to FIG. 1H, FIG. 1J to FIG. 1L, FIG. 1O to FIG. 1R, describes a process for producing a layer arrangement in accordance with a seventh exemplary embodiment of the invention.

First of all, as described above with reference to FIG. 1A to FIG. 1H, FIG. 1J to FIG. 1L, the layer sequence 144 is formed.

To obtain the layer sequence 158 shown in FIG. 1O, a further photoresist layer 160 comprising decomposable and photoactive material is spun on and dried.

To obtain the layer sequence 162 shown in FIG. 1P, the further photoresist layer 160 is exposed using an interconnect photomask. The interconnect photomask is selected in such a manner that the location of the further photoresist layer 160 above which the via hole 142 was previously arranged is exposed. The proportion of the further photoresist layer 160 which is located in the original via hole 142 is therefore exposed and removed during the subsequent developing step. This results in the typical dual Damascene structure shown in FIG. 1P, in which the via hole 142 and an interconnect 120 are uncovered in the covering layer 124. Furthermore, a further decomposable structure 164 has been formed from the patterned further photoresist layer 160.

To obtain the layer sequence 166 shown in FIG. 1Q, further copper interconnects 166 are formed, as described above with reference to FIG. 1E, FIG. 1F. At the same time, the via hole 142 is filled with copper material. In other words, both the via hole 142 and the surface regions of the layer sequence 162 which are free of the further decomposable structure 164 are covered with copper material by means of a liner (for example tantalum) and copper seed layer deposition. Excess copper and liner material is removed using a CMP process, resulting in a planar surface of the layer sequence 166.

To obtain the layer arrangement 170 shown in FIG. 1R, the layer sequence 166 shown in FIG. 1Q is processed in a similar manner as that described above with reference to FIG. 1G, FIG. 1H. First of all, a further covering layer 172 is applied to the surface of the layer sequence 166. Then, the remaining photoresist material of the further decomposable structure 164 is removed by conditioning, with the result that further cavities 174 are formed.

The text which follows describes a process for producing a layer arrangement in accordance with an eighth exemplary embodiment of the invention.

A polyimide precursor (polyamidocarboxylic acid), produced from diaminodiphenyl ether and benzenetetracarboxylic dianhydride, from a solution in N-methylpyrrolidone is applied to a silicon substrate (wafer) by means of a spin coating technique and is dried on a heating plate for 2 minutes at 120° C. Then, the coated substrate is annealed in an annealing furnace under a nitrogen atmosphere for approximately 60 minutes at approximately 420° C. The annealing converts the polyimide precursor into polyimide. The layer thickness of this polyimide film, which serves as a dielectric layer, is approximately 1 μm.

Then, a solution of a polyester (poly-1,4-butyleneglycol terephthalate) is applied to the dielectric by means of a spin coating technique and is dried for approximately 3 minutes at approximately 150° C. on a heating plate. The thickness of this layer is approximately 1 μm. An approximately 200 nm thick silicon dioxide layer as hard mask for the patterning of the decomposable polyester layer is applied to the polyester layer by means of the CVD (chemical vapour deposition) process. The silicon dioxide layer is coated with a resist layer which is composed of the following components; 20 parts by weight of m-Kresol-Novolak, 6 parts by weight of a triester of 2,3,4-trihydroxybenzophenone and naphthoquinone-diazide-4-sulphonic acid, and 80 parts by weight of methoxypropylacetate.

After the resist has been dried for 2 minutes at 100° C., its layer thickness is approximately 0.8 μm.

The resist layer is exposed (exposure wavelength 365 nm) using a photomask (land-trench mask), is developed using an aqueous-alkaline developer AZ 303 produced by Celanese for approximately 60 seconds and dried at 100° C. for 1 minute. The vertical height of the resist structures is approximately 0.8 μm.

The resist structure is transferred firstly into the silicon dioxide using a CHF₃ plasma etching process for 30 seconds and then into the decomposable polyester layer by means of O₂ plasma etching for 60 seconds. The silicon dioxide layer in this case serves as an etching mask. During this transfer of the structures, the photoresist material is removed as a result of the etching.

Then, the silicon dioxide layer is removed by being treated with a HF solution for approximately 60 seconds, the layer sequence is rinsed with distilled water and dried for 60 seconds at 100° C.

The polyester structures on polyimide which are produced in accordance with this production process approximately correspond to the layer sequence 110 shown in FIG. 1B. Working on the basis of this layer sequence, it is possible then to continue in accordance with one of the production processes presented above in order to obtain a layer arrangement in accordance with the invention.

The following publications are cited in this document:
[1] B. P Shieh, L. C. Bassmann, D.-K. Kim, K. C. Saraswat, M. D. Deal, J. P. McVittie, R. S. List, S. Nag, L. Ting, Proc. IEEE, IITC 1998, 125-127
[2] Demolliens, O. et al., Proceedings of IITC 2000, 276, 277
[3] Kohl, P et al. (2000) “Air-Gaps in 0.3 μm Electrical Interconnections”, IEEE Electron Device Letters, Vol. 21, Nr. 12, p. 557-559
[4] DE 44 41 898 C1
[5] U.S. Pat. No. 5,461,003
[6] U.S. Pat. No. 6,342,722 B1

1. Layer arrangement
with a substrate;
having a layer which is arranged on the substrate and includes a first subregion comprising decomposable material and a second subregion which is arranged next to the first subregion and has a useful structure comprising a non-decomposable material;
having a covering layer on the layer comprising decomposable material and the useful structure;
having an electrically conducted passivation layer at least between the useful structure and the covering layer;
the layer arrangement being designed in such a manner that the decomposable material can be removed from the layer arrangement by diffusing through the covering layer.

2. Layer arrangement according to claim 1, having an intermediate layer between the substrate and the layer comprising decomposable material and the useful structure.

3. The layer arrangement as claimed in claim 1 or 2, in which the substrate includes silicon.

4. The layer arrangement as claimed in claim 2 or 3, in which the covering layer and/or the intermediate layer is made from dielectric material.

5. The layer arrangement as claimed in one of claims 2 to 4, in which the covering layer and/or the intermediate layer comprises one or a combination of the materials
silicon oxide;
silicon nitride;
SiLK;
porous SiLK;
oxazole;
porous oxazole;
Black Diamond;
Coral;
Nanoglass;
JSR LKD;
polybenzoxazole;
polybenzimidazole;
polyimide;
polyquinoline;
polyquinoxaline;
polyarylene; and
polyarylene ether.

6. The layer arrangement as claimed in one of claims 1 to 5, in which the covering layer is designed in such a manner that it is permeable to decomposable material which has decomposed.

7. The layer arrangement as claimed in one of claims 1 to 6, in which the useful structure is made from an electrically conductive material.

8. The layer arrangement as claimed in claim 7, in which the useful structure includes
silver;
a silver alloy;
tungsten;
tungsten silicide;
aluminium;
an aluminium alloy;
copper; and/or
a copper alloy.

9. Layer arrangement according to one of claims 1 to 6, in which the useful structure is made from a dielectric material.

10. Layer arrangement according to claim 9, in which the useful structure includes
silicon dioxide;
silicon nitride; and/or
a ceramic material.

11. The layer arrangement as claimed in one of claims 1 to 10, in which the decomposable material is thermally decomposable.

12. The layer arrangement as claimed in one of claims 1 to 11, in which the decomposable material includes one or a combination of
polyester;
polyether;
polyethylene glycol;
polypropylene glycol;
polyethylene oxide;
polypropylene oxide;
polyacrylate;
polymethacrylate;
polyacetal;
polyketal;
polycarbonate;
polyurethane;
polyether ketone;
cycloaliphatic polymer;
polynorbornene;
aliphatic polyamide;
Novolak;
polyvinylphenol;
an epoxy compound;
copolymer of these compounds; and
terpolymer of these compounds.

13. Layer arrangement according to one of claims 1 to 12, in which the decomposable material is photosensitive.

14. Layer arrangement according to one of claims 1 to 13, in which at least one support structure is formed in the layer arranged between the substrate and the covering layer.

15. Layer arrangement according to one of claims 1 to 14, having a protective structure, which runs along the lateral boundary of the substrate, to protect the useful structure from environmental influences.

16. Layer arrangement according to one of claims 1 to 15, having a passivation layer which at least partially surrounds the useful structure.

17. A process for producing a layer arrangement, in which
a layer which includes a first subregion comprising decomposable material and a second subregion which is arranged next to the first subregion and has a useful structure comprising a non-decomposable material is formed on a substrate;
a covering layer is formed on the layer comprising decomposable material and the useful structure;
an electrically conductive passivation layer is formed at least between the useful structure and the covering layer;
the layer arrangement being designed in such a manner that the decomposable material can be removed from the layer arrangement by diffusing through the covering layer.

18. Process according to claim 17, in which the decomposable material is removed from the layer arrangement.

19. Process according to claim 18, in which the decomposable material is removed from the layer arrangement by means of thermal decomposition.

20. Process according to one of claims 17 to 19, in which
the useful structure is formed from copper;
the useful structure is at least partially sheathed by a passivation layer, which passivation layer
is formed from cobalt-tungsten-phosphorus, cobalt-tungsten-boron, cobalt-phosphorus or ruthenium by means of an electroless deposition process; or
is formed from tantalum, tantalum nitride, titanium nitride, tungsten, tungsten nitride or tungsten carbide by means of a chemical vapour deposition process.

21. Process according to one of claims 17 to 20, in which the layer comprising decomposable material and the useful structure is formed by
decomposable material being deposited and patterned;
material of the useful structure being deposited;
the surface of the layer sequence obtained in this way being planarized.

22. Process according to one of claims 17 to 20, in which the layer comprising decomposable material and the useful structure is formed by
material of the useful structure being deposited and patterned;
decomposable material being deposited;
the surface of the layer sequence obtained in this way being planarized.

23. Process according to one of claims 17 to 22, in which at least one additional layer stack is formed on the covering layer, the additional layer stack having an additional covering layer on an additional layer comprising decomposable material and a useful structure.

24. Process according to claim 23, in which useful structures which are separated from one another by a covering layer are coupled to one another by at least one contact hole being introduced into the covering layer and being filled with electrically conductive material.
